(19) United States
(12) Patent Application Publication
(10) Pub. No.: US 2007/0080695 A1
(43) Pub. Date: Apr. 12, 2007

(54) Testing system and method for a MEMS sensor

(76) Inventors: Gary Arthur Morrell, Colorado Springs, CO (US); Christopher Sean Nickerson, Florissant, CO (US)

Correspondence Address: LAW OFFICE OF DALE B. HALLING, LLC, 655 SOUTHPOINTE CT, SUITE 100, COLORADO SPRINGS, CO, 80906, US

(21) Appl. No.: 11/546,181

(22) Filed: Oct. 11, 2006

Related U.S. Application Data
(60) Provisional application No. 60/725,270, filed on Oct. 11, 2005.

(51) Int. Cl. G01R 27/26

(52) U.S. Cl. 324/658

(57) ABSTRACT

A test system and method for a MEMS sensor has an electrical input signal that drives a capacitor of the MEMS sensor. The capacitor has a movable plate. A mechanical actuator provides a mechanical stimulus to the MEMS sensor. A detection system detects an output signal of the capacitor. The system determines a resonant frequency, spring constant, damping ratio, frequency response and a hysteresis for the capacitor.

### RELATED APPLICATIONS

The present invention claims priority on provisional patent application, Ser. No. 60/725,270, filed on Oct. 11, 2005, entitled “Drive sense technology to measure dynamic capacitance changes of a micro-machined variable capacitor” and is hereby incorporated by reference.

### FIELD OF THE INVENTION

The present invention relates generally to the field of micro-electrical mechanical system (MEMS) sensors and more particularly to a testing system and method for a MEMS sensor.

### BACKGROUND OF THE INVENTION

Micro-machined or Micro-Electrical Mechanic System (MEMS) sensors frequently use variable capacitors that may be used to measure mechanical displacement due to external stimulus, or to induce movement via electrostatic deflection between a fixed and a movable capacitor plate(s). Some sensing examples would be to measure the movement of a proof mass in an inertial sensor, or the diaphragm of a pressure sensor as the diaphragm responds to pressure changes. Actuator examples would include a movable capacitor plate connected to a mirror which can bend a light beam, a diaphragm to convert electrical energy into acoustic energy (a speaker), or may implement a self-test function by moving an inertial proof mass or flexing the diaphragm in a pressure sensor.

Characterization and production verification testing of micro-machined capacitive devices often is limited to performing static capacitance measurements with the movable capacitor plate in its rest position, or, if self-test capability is available, deflecting the movable plate to several positions within its range of motion and performing a static capacitive measurement at each position. While static capacitance measurements are useful for ascertaining the basic function of a micro-machined capacitive device, they do not reveal anything about the device's dynamic characteristics; such as the amplitude deflection of the capacitor plate versus frequency (system frequency response), damping characteristics of the mechanical system, or system response to a step function input.

Thus there exists a need for a testing system and method that can test a MEMS sensors dynamic characteristics.

### SUMMARY OF THE INVENTION

A test system and method for a MEMS sensor that overcomes these and other problems has an electrical input signal that drives a capacitor of the MEMS sensor. The capacitor has a movable plate. A mechanical actuator provides a mechanical stimulus to the MEMS sensor. A detection system detects an output signal of the capacitor. The system determines a resonant frequency, spring constant, damping ratio, frequency response and a hysteresis for the capacitor. As a result, the user has a complete picture of the MEMS sensor's dynamic characteristics.

### BRIEF DESCRIPTION OF THE DRAWINGS

FIG. 1 is a block diagram of a system for testing a MEMS sensor in accordance with one embodiment of the invention; and

FIG. 2 is flow diagram of the tests for a MEMS sensor in accordance with one embodiment of the invention.

### DETAILED DESCRIPTION OF THE DRAWINGS

The present invention is directed to a test system and method for a MEMS sensor that has an electrical input signal that drives a capacitor of the MEMS sensor. The capacitor has a movable plate. A mechanical actuator provides a mechanical stimulus to the MEMS sensor. A detection system detects an output signal of the capacitor. The system determines a resonant frequency, spring constant, damping ratio, frequency response and a hysteresis for the capacitor. As a result, the user has a complete picture of the MEMS sensor's dynamic characteristics.

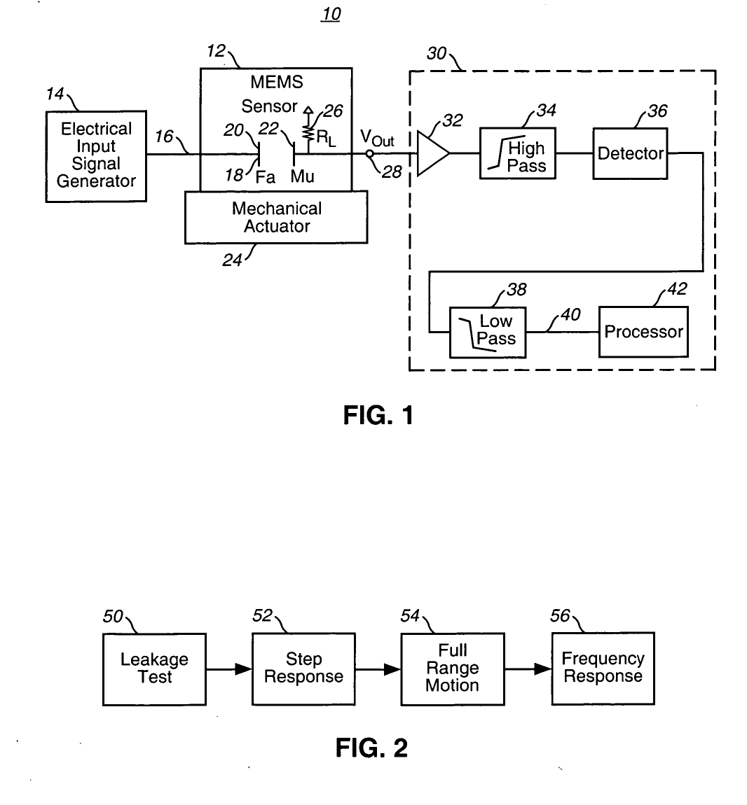

FIG.1 is a block diagram of a system 10 for testing a MEMS sensor 12 in accordance with one embodiment of the invention. The system 10 has an input electrical signal generator 14. The input signal 16 is applied to a capacitor 18 of the MEMS sensor 12. The capacitor 18 has a fixed plate (Fa) 20 and a movable plate (Ma) 22. The MEMS sensor 12 is attached to a mechanical actuator 24, which provides a mechanical stimulus to the MEMS sensor 12. The movable plate 22 of the capacitor 18 is coupled to a load (R_{L}) 26. The output signal 28 of the MEMS sensor 12 is received by a detection system 30. The detection system 30 has an amplifier 32 that amplifies the output signal 28. The amplified signal is high pass filtered 34 to remove any effects of parasitic coupling. The high pass filtered signal is then detected by a detector 36. Next the detected signal is low pass filtered 38. The output 40 is then analyzed by a processor 42. The test system 10 can be used to perform a number of different dynamic tests.

FIG. 2 is flow diagram of the tests for a MEMS sensor in accordance with one embodiment of the invention. The first test shown is a leakage test 50. In this case a voltage level is generated by the electrical input signal generator 14. The output current is detected by the detection system 30. This test determines if there are electrical connection problems with the capacitor. The next test is a step response test 52. In this case, the electrical input signal generator 14 applies a RF signal, usually an essential single frequency sine wave, to the capacitor 18. The mechanical actuator 24 applies a step response mechanical stimulus to the MEMS sensor 12. The output 28 is detected by the detection system 30. The processor 42 determines a resonant frequency, spring constant and damping ratio of the movable plate 22 with this test. The next test is a full range motion test or hysteresis test 54. In this test, a positive then a negative voltage ramp is generated by the generator 14 and applied to the capacitor 18. The increasing voltage mechanical path is compared with the decreasing voltage mechanical path. Hysteresis, slopes and nonuniform slope changes are capture and characterized by the processor 42. The final test is a frequency response test 56. In this test, the electrical input signal generator 14 applies a RF signal, usually an essential single frequency sine wave, to the capacitor 18. The mechanical actuator 24 applies a series of swept sine waves. From this the “mechanical bandwidth” of the movable plate is determined.

Thus there has been described a testing system and method that can test a MEMS sensors dynamic characteristics.

While the invention has been described in conjunction with specific embodiments thereof, it is evident that many alterations, modifications, and variations will be apparent to those skilled in the art in light of the foregoing description. Accordingly, it is intended to embrace all such alterations, modifications, and variations in the appended claims.

What is claimed is:

1. A testing system for a MEMS sensor, comprising:
an input RF signal coupled to a capacitor of the MEMS sensor, wherein the capacitor has a movable plate;
a mechanical actuator mechanically displacing the MEMS sensor; and
a detection system receiving an output signal from the capacitor.

2. The system of claim 1, wherein the detection system has a low pass filter.

3. The system of claim 2, wherein the detection system has a high pass filter that filters the output signal of the capacitor.

4. The system of claim 1, wherein the mechanical actuator has a step function output.

5. The system of claim 4, wherein the mechanical actuator has a sinusoidal output.

6. The system of claim 1, wherein the detection system determines a resonant frequency of the capacitor.

7. The system of claim 6, wherein the detection system determines a frequency response of the movable plate.

8. A method of testing a MEMS sensor, comprising the steps of:
a) applying an RF signal to a capacitor of the MEMS sensor, wherein the capacitor has a movable plate;
b) applying a mechanical stimulus to the MEMS sensor; and
c) detecting an output signal from the capacitor.

9. The method of claim 8, wherein step (c) further includes the step of:
c1) amplifying the output signal;
c2) high pass filtering the output signal to form a filtered output signal.

10. The method of claim 9, further including the steps of:
c3) detecting the filtered output signal to form a detected signal;
c4) low pass filtering the detected signal.

11. The method of claim 8, further including the step of:
d) determining a damping ratio of the movable plate.

12. The method of claim 11, further including the step of:
e) determining a frequency response of the movable plate.

13. The method of claim 8, further including the steps of:
d) turning off the RF signal;
e) performing a hysteresis test.

14. The method of claim 13, further including the step of:
f) performing a leakage test.

15. A testing system for a MEMS sensor, comprising:
an electrical input signal applied to a capacitor of a MEMS sensor, wherein the capacitor has a movable plate;
a mechanical actuator mechanically displacing the MEMS sensor; and
a detection system receiving an output signal from the capacitor.

16. The system of claim 15, wherein the electrical input signal is an RF signal.

17. The system of claim 15, wherein the electrical input signal is a voltage ramp.

18. The system of claim 15, wherein the detection system determines a spring constant of the movable plate.

19. The system of claim 18, wherein the detection system determines a resonant frequency of the movable plate.

20. The system of claim 18, wherein the detection system determines a damping ratio of the movable plate
